(19) United States
(12) Patent Application Publication
(10) Pub. No.: US 2014/0069478 A1
(43) Pub. Date: Mar. 13, 2014

(54) APPARATUS FOR CONVERTING THERMAL ENERGY INTO ELECTRICAL ENERGY

(71) Applicant: FRIEDRICH BOYSEN GMBH & CO. KG, Altensteig (DE)

(72) Inventors: Roland GAUSS, Simmersfeld-Oberweiler (DE); Karl STOCKINGER, Ebhausen (DE)

(73) Assignee: FRIEDRICH BOYSEN GMBH & CO. KG, Altensteig (DE)

(21) Appl. No.: 14/024,251

(22) Filed: Sep. 11, 2013

(30) Foreign Application Priority Data
Sep. 11, 2012 (DE) 10 2012 216 042.6

(51) Int. Cl. H01L 35/30

(52) U.S. Cl. CPC H01L 35/30
USPC 136/210

(57) ABSTRACT

An apparatus for converting thermal energy into electrical energy comprises at least one thermoelectric module which has a hot side provided for a contact with a heat source and a cold side provided for a contact with a heat sink, a heating passage which can be flowed through by a hot fluid and which is in thermoconductive communication with the hot side of the thermoelectric module, and a cooling passage which can be flowed through by a cooling fluid and which is in thermoconductive communication with the cold side of the thermoelectric module. Provision is made that the cooling passage has at least one cooling passage opening facing toward the cold side of the thermoelectric module and/or that the heating passage has at least one heating passage opening facing toward the hot side of the thermoelectric module. The thermoelectric module is covered by a layer or film of an electrically insulating material at least in the region of the cooling passage opening and/or of the heating passage opening.

The present invention relates to an apparatus for converting thermal energy into electrical energy, comprising at least one thermoelectric module which has a hot side provided for a contact with a heat source and a cold side provided for a contact with a heat sink, a heating passage which can be flowed through by a hot fluid and which is in thermoconductive communication with the hot side of the thermoelectric module, and a cooling passage which can be flowed through by a cooling fluid and which is in thermoconductive communication with the cold side of the thermoelectric module, wherein the cooling passage has at least one cooling passage opening facing toward the cold side of the thermoelectric module and/or the heating passage has at least one heating passage opening facing toward the hot side of the thermoelectric module.

Such apparatus are also called “thermoelectric generators” (TEG) and are used in various types of utilization of exhaust gas heat. Thermoelectric generators can, for example, be used for the utilization of exhaust gas heat of internal combustion engines in that a portion of the thermal energy of the motor vehicle is supplied in order ultimately to save fuel. What is decisive for a yield of electrical energy which is as large as possible is, in addition to the efficiency of the thermoelectric module, above all a temperature difference which is as large as possible between the heat source and the heat sink.

Heating passages and/or cooling passages provided with one or more openings improve the heat transfer between the thermoelectric module and the corresponding heat carrier fluid since the normally present passage wall is omitted as an additional heat transfer resistance at least in the region of the respective opening. Such openings therefore make possible a higher total efficiency in a thermoelectric generator. A thermoelectric generator having a cooling passage open toward the cold side of the thermoelectric modules is disclosed in WO 2012/079662.

In practice, however, it is difficult to operate thermoelectric generators having passage openings efficiently. A particular problem is that the surface of conventional thermoelectric modules always has certain irregularities caused by manufacture. Problematic leaks and leak flows can thereby occur. To prevent these problems, the thermoelectric module can be accommodated in a housing which has a planar outer surface. However, this in turn increases the heat transfer resistance.

It is an object of the invention to improve thermoelectric generators having heating passage openings and/or cooling passage openings.

The object is satisfied by an apparatus having the features of claim 1.

In accordance with the invention, the thermoelectric module is covered at least in the region of the cooling passage opening and/or the heating passage opening by a layer or film of an electrically insulating material.

The cooling passage or the heating passage is hereby electrically decoupled from the thermoelectric module so that separate outer insulation elements such as an insulating housing are superfluous. The electrically insulating layer or film thus makes possible a stable operation of the thermoelectric generator despite the existing passage openings.

Further developments of the invention are set forth in the dependent claims, in the description and in the enclosed drawings.

The electrically insulating layer or film is preferably gastight and/or watertight. The layer or film thus not only provides an electrical insulation, but also a sealing of the passage in the region of the opening. In this manner, unwanted leak flows to external as well as cross-talk between adjacent passage sections can be avoided.

The electrically insulating layer or film can, for example, comprise polytetrafluoroethylene (PTFE). This material has proved particularly favorable with respect to the electrical insulation effect and the sealing effect. Silicone films and permanently elastic lacquers can also be considered.

In accordance with an embodiment of the invention, the electrically insulating layer or film is applied, in particular sprayed, over the full surface onto the cold side and/or onto the hot side of the thermoelectric module or onto a surface formed by the cold side and/or the hot side of the thermoelectric module and by an enclosure for the thermoelectric module. A particularly reliable insulation and sealing is thereby ensured.

Provision can furthermore be made that the thermoelectric module is applied directly, and in particular without a housing, to the cooling passage and/or to the heating passage. However, a housed and therefore already electrically insulated thermoelectric module such as is customary in the technical area is therefore not used, but a housing is directly dispensed with in order hereby to reduce the heat transfer between the surface of the thermoelectric module and the corresponding heat carrier fluid. The required separation of the respective heat carrier fluid is established via the layer or film of the electrically insulating material which can be configured as relatively thin and only forms a low heat transfer resistance.

In accordance with an aspect of the invention, the thermoelectric module is completely covered or surrounded by a layer or film of an electrically insulating material. This allows a simple manufacture and ensures a full-surface electrical insulation. The thermoelectric module is so-to-say encapsulated by the electrically insulating layer or film. In addition, the layer or film can contribute to compensating irregularities on the surface of the thermoelectric module.

A further development of the invention provides that the electrically insulating layer or film is applied directly to a thermoelectrically active surface of the thermoelectric module. This means that additional intermediate layers are dispensed with to impede as little as possible the heat transfer between the surface of the thermoelectric module and the respective flowing fluid. For example, the electrically insulating layer can be sprayed onto the thermoelectrically active surface of the thermoelectric module, which is only associated with a small manufacturing effort.

The invention will be described in the following by way of example with reference to the drawings.

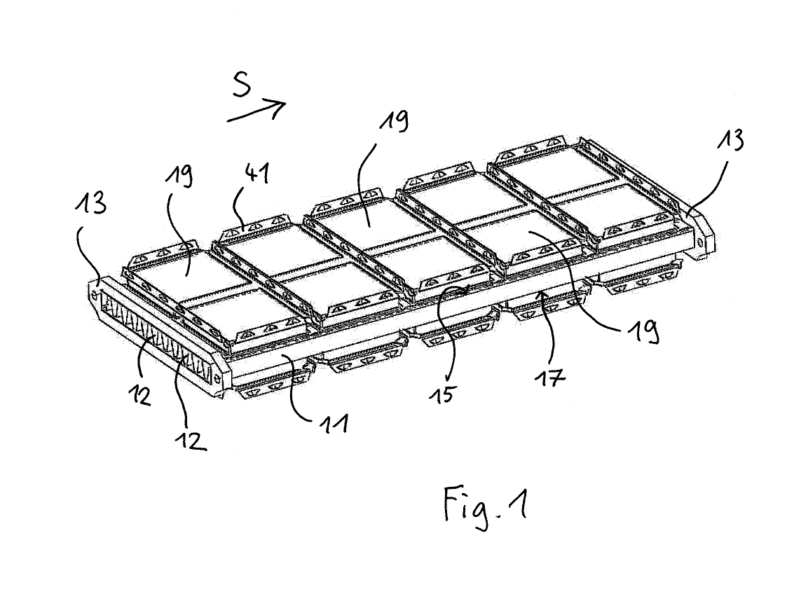

FIG. 1 is a perspective representation of an apparatus in accordance with the invention for converting thermal energy into electrical energy which is attached to an exhaust gas passage of an internal combustion engine;

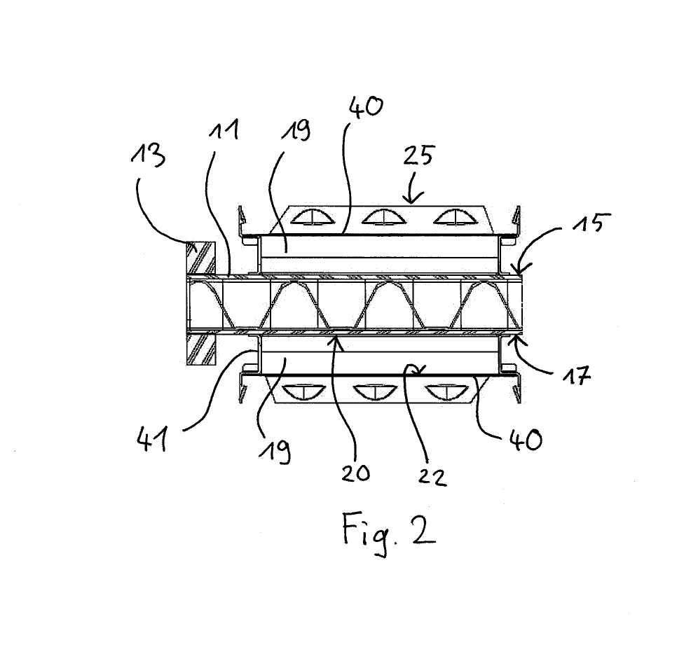

FIG. 2 is a broken-away partial representation of the apparatus in accordance with FIG. 1;

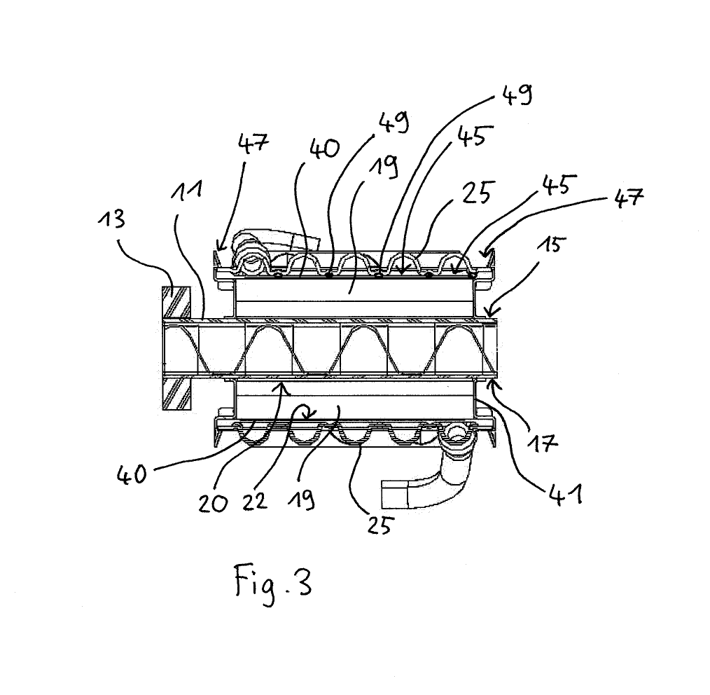

FIG. 3 shows a further section through the apparatus in accordance with FIG. 1, with the passage extent of a cooling passage of the apparatus being illustrated; and

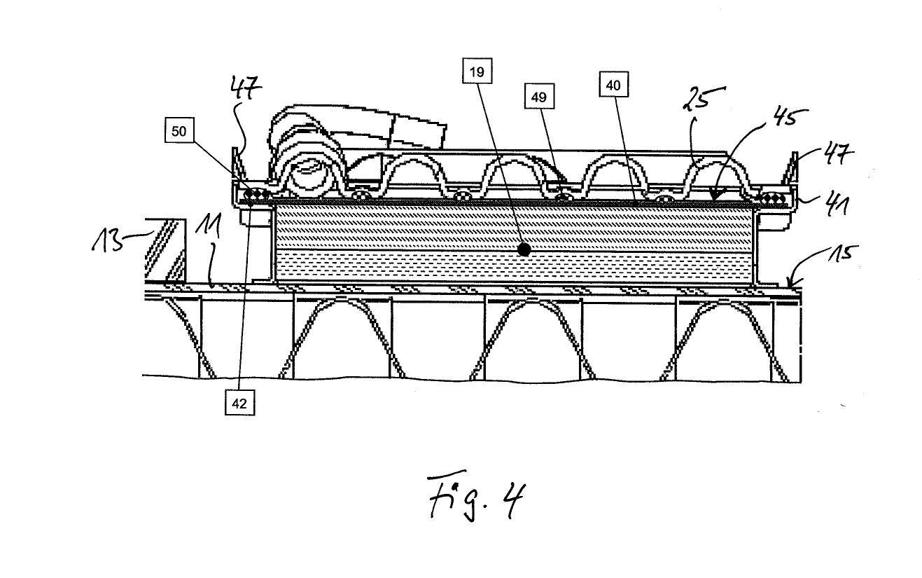

FIG. 4 shows an enlarged section through a part of a variant of FIG. 3.

In accordance with FIG. 1 an exhaust gas passage 11 serves for conducting a hot exhaust gas from an internal combustion engine, not shown, along a flow direction S into the atmosphere. The exhaust gas passage 11 has a rectangular, flattened cross-section and is split into a plurality of secondary passages 12. A flange 13 is provided at an end face of the exhaust gas passage 11 at a flow inlet side and serves for connecting the exhaust gas passage 11 to a preceding component of the associated exhaust train. A flange 13 is equally provided at the end face of the exhaust gas passage 11 at the flow outlet side. Respective arrangements of thermoelectric modules 19 are provided at the upper side 15 and at the lower side 17 of the exhaust gas passage 11 to convert the thermal energy of the flowing exhaust gas into electrical energy.

In accordance with the sectional representations of FIGS. 2 and 3, each thermoelectric module 19 is aligned such that the hot side 20 provided for a contact with a heat source faces toward the exhaust gas passage 11. A cooling passage 25 which can be flowed through by a cooling fluid, in particular water, is provided at the opposite cold side 22 of each thermoelectric module 19. Each cooling passage 25 is configured as a half-shell element open at one side, i.e. the individual passage sections have openings 45 which face toward the cold side 22 of the respective thermoelectric module 19. Each cooling passage 25 substantially completely covers the cold side 22 of the associated thermoelectric module 19. Each cooling passage 25 is thus substantially completely open viewed in the direction of the cold side 22 of the thermoelectric module 19. The cooling passage 25 have been omitted for reasons of simplification in FIG. 1.

An electrically insulating layer or film 40 of polytetrafluoroethylene (PTFE) or of another suitable material is located between the cold side 22 of each thermoelectric module 19 and the associated cooling passage 25. The layer or film 40 is directly applied to the thermoelectrically active surface of the respective thermoelectric module 19, that is the thermoelectric modules 19 are not accommodated in a housing as customary in the technical area.

An arrangement of thermoelectric modules 19 are first cemented into a grid-like frame structure 41 of metal for manufacturing an apparatus in accordance with the invention. Subsequently, the layer or film 40 is sprayed over the full surface onto the cold sides 22 of the thermoelectric modules 19. The half-shell like cooling passages 25 are then placed onto the frame structure 41 from the outside and are latched into it, for which purpose a latch mechanism 47 is provided. Elastic seals 49 are arranged between the cooling passages 25 and the layer or film 40. The cooling passages 25 can generally also be adhesively bonded to the layer or film 40.

In the embodiment shown in FIG. 4, the layer or film 40 is drawn in a plane 42 up to and over the frame structure 41 and, together with the seals 49 between the cooling passages 25 and the peripheral seal 50, terminates the cooling passages 25.

During the operation of the apparatus, the flowing cooling fluid, in particular water, in the individual passage sections of the cooling passages 25 moves into direct contact with the thermoelectric modules 19, with only the layer or film 40 being located between the cooling fluid and the thermoelectrically active surface. The layer or film 40 in this respect acts both as an electrical insulation between the thermoelectrically active surface and the cooling fluid and as a fluid-tight closure of the cooling passage 25.

In the embodiment shown, the electrically insulating layer or film 40 is provided only at the cold side 22 of the thermoelectric modules 19. Equally, however, the exhaust gas passage 11 could also have openings and could be sealed by an electrically insulating layer or film provided at the hot side 20 of the thermoelectric modules 19.

Different from the embodiment shown, a plate-like frame structure can be provided which forms a flush enclosure for the thermoelectric modules. In this case, it is favorable from a technical manufacturing aspect to apply the layer or film over the full surface onto the thermoelectric modules 19 through the cold sides 22 and onto the frame structure enclosing them.

The arrangement of exhaust gas passage 11, frame structure 41, thermoelectric modules 19 and cooling passages 25 is, for example, elastically supported in a metallic protective housing by means, for example, of a fibrous mat, which is, however, not shown in the Figures.

### REFERENCE NUMERAL LIST

11 exhaust gas passage
12 secondary passage
13 flange
15 upper side
17 lower side
19 thermoelectric module
20 hot side
22 cold side
25 cooling passage
40 layer or film
41 frame structure
45 cooling passage opening
47 latch mechanism
49 seal
40 seal
S flow direction

1. An apparatus for converting thermal energy into electrical energy, comprising
at least one thermoelectric module (19) which has a hot side (20) provided for a contact with a heat source and a cold side (22) provided for a contact with a heat sink;
a heating passage (11) which can be flowed through by a hot fluid and which is in thermoconductive communication with the hot side (20) of the thermoelectric module (19);
a cooling passage (25) which can be flowed through by a cooling fluid and which is in thermoconductive communication with the cold side (22) of the thermoelectric module (19),
said cooling passage (25) having at least one cooling passage opening (45) facing toward the cold side (22) of the thermoelectric module (19);
and/or said heating passage (11) having at least one heating passage opening facing toward the hot side (20) of the thermoelectric module (19),
said thermoelectric module (19) being covered at least in the region of the cooling passage opening (45) and/or of the heating passage opening by a layer or film (40) of an electrically insulating material.

2. The apparatus in accordance with claim 1, wherein the layer or film (40) is gastight and/or watertight.

3. The apparatus in accordance with claim 1, wherein the layer or film (40) comprises polytetrafluoroethylene (PTFE).

4. The apparatus in accordance with claim 1, wherein the layer or film (40) is applied over the full surface onto the cold side (22) and/or onto the hot side (20) of the thermoelectric module (19) or onto a surface formed by the cold side (22) and/or by the hot side (20) of the thermoelectric module (19) and by an enclosure for the thermoelectric module (19).

5. The apparatus in accordance with claim 4, wherein the layer or film is applied by spraying.

6. The apparatus in accordance with claim 1, wherein the thermoelectric module (19) is applied directly to the cooling passage (25) and/or to the heating passage (11).

7. The apparatus in accordance with claim 1, wherein the thermoelectric module (19) is applied directly without a housing to the cooling passage (25) and/or to the heating passage (11).

8. The apparatus in accordance with claim 1, wherein the thermoelectric module (19) is completely covered or surrounded by a layer or film (40) of an electrically insulating material.

9. The apparatus in accordance with claim 1, wherein the layer or film (40) is applied directly to a thermoelectrically active surface of the thermoelectric module (19).
